(19) United States
(12) Patent Application Publication
(10) Pub. No.: US 2009/0320998 A1
(43) Pub. Date: Dec. 31, 2009

(54) ARTICLES AND METHODS INCLUDING PATTERNED SUBSTRATES FORMED FROM DENSIFIED, ADHERED METAL POWDERS

(75) Inventors: Terry S. Nees, Shoreview, MN (US); Thanh-Huong T. Do, Oakdale, MN (US); Steven C. Hackett, Oakdale, MN (US); Matthew J. Michel, St. Paul, MN (US); Katherine A. Brown, Lake Elmo, MN (US)

Correspondence Address: 3M INNOVATIVE PROPERTIES COMPANY, PO BOX 33427, ST. PAUL, MN, 55133-3427, US

(73) Assignee: 3M INNOVATIVE PROPERTIES COMPANY

(21) Appl. No.: 12/114,158

(22) Filed: May 2, 2008

Related U.S. Application Data
(62) Division of application No. 11/385,008, filed on Mar. 20, 2006.

(51) Int. Cl. H05K 3/02

(52) U.S. Cl. 156/219

(57) ABSTRACT

In general the disclosure relates to manufacturing methods for producing conductive patterns on flexible substrates. For example, a layer of a metal powder composition is deposited onto an adhesive overlaying a substrate. Pressure is applied to the metal powder composition on the adhesive coated substrate web by a die having one or more projections, in order to reproduce a pattern on the substrate. The metal powder is compressed by the projections of the die, thereby densifying the powder and causing it to adhere to the adhesive in a reproduction of the die pattern. The metal powder does not adhere substantially in uncompressed regions, and may be removed. In this manner, a metal powder composition may be densified and adhered to a substrate forming a web of flexible circuit elements, for example, circuit elements such as antennas, resistors, capacitors, inductive coils, conduction pads and the like.

This application is a divisional of U.S. Ser. No. 11/385,008, filed Mar. 20, 2006, the disclosure of which is incorporated by reference in its entirety herein.

### TECHNICAL FIELD

The invention relates to methods for manufacturing patterned substrates using metal powders. The invention further relates to flexible electrical circuits and circuit elements.

### BACKGROUND

Substrates bearing conductive patterns, such as printed circuit boards, have many uses in the electronics industry. Printed circuits may be made by applying pressure with a heated platen to sinter metallic particles to a non-flexible, adhesive-coated substrate. Metal particles may also be mixed with a curable liquid organic binder and embossed into a rigid adhesive-coated substrate by applying heat and pressure to a die platen. Printed circuits may also be produced by embossing conductive metal granules mixed with an inorganic matrix material onto a heat-softenable substrate in a press. Silk screen printing methods may alternatively be used to apply liquid ink compositions, including mixtures of organic binder materials with organometallic or metallic particles, to heat-resistant substrates that are heated to sinter the metal and form a conductive circuit pattern. Recently, metal particles have been applied to compressible substrates such as paper and compressed to produce low cost printed circuits.

However, compressible substrates such as paper suffer from a tendency to absorb and release water, which may result in poor dimensional stability and variable electronic performance that may be undesirable in certain applications. Moreover, the use of inorganic and organometallic compounds is limited to specific combinations of materials and particular substrates, which often requires high processing temperatures and pressures to sinter the metals into a conductive circuit trace. Furthermore, known methods for embossing metal powders on polymeric substrates are limited to sheet-fed batch processing of rigid substrates using platen presses, and are not amenable to continuous web processing of flexible substrates.

### SUMMARY

In general, the invention relates to flexible circuits made from densified metal powders, and to methods and systems for manufacturing electrically conductive patterns on flexible, substantially incompressible substrates using densified metal powders.

In one embodiment, the invention is directed to an article including a flexible substrate, an adhesive layer covering a surface of the flexible substrate, and a densified metal powder adhered to the adhesive layer and forming a pattern on the surface of the adhesive layer. In certain additional embodiments, the article includes a second adhesive layer covering a second surface of the flexible substrate, and a densified metal powder, less than 100% dense, overlaying the second adhesive layer. In some additional embodiments, the article includes an overlayer covering at least a portion of the densified metal powder.

In certain exemplary embodiments, the densified metal powder forms a pattern on the first surface of the flexible substrate. In some exemplary embodiments, the pattern defines an electrically conductive circuit. In additional exemplary embodiments, the pattern defines an antenna for a radio frequency identification tag.

In another embodiment, the invention relates to a process for making a continuous roll of flexible web material bearing a conductive metal pattern. The method includes the steps of applying an adhesive layer to a first surface of a continuous flexible substrate web, applying a metal powder to the adhesive layer, and compressing a portion of the metal powder on the first surface for a time and at a pressure sufficient to form an electrically conductive pattern of densified metal powder. In certain embodiments, compressing includes compressing the metal powder to at least about 90% and at most less than 100% dense. In other embodiments, compressing includes applying a pressure to the metal powder with a patterned die to form a densified, adhered metal pattern corresponding to raised elements of a patterned die. In further embodiments, the process includes removing uncompressed metal powder from a portion of the adhesive layer.

In a further embodiment, the invention is directed to a system for making a continuous flexible substrate bearing a pattern of compressed metal powder, said system including a web handling assembly for feeding a continuous flexible substrate bearing a first adhesive layer from a supply roll to a take-up roll, a first powder applicator for applying a metal powder to the first adhesive layer at a position between the supply roll and the take-up roll, a patterned die having raised elements in the form of a pattern positioned between the first powder applicator and the take-up roll, and a powder removal device for removing uncompressed metal powder from the first adhesive layer. In certain embodiments, the patterned die is configured to apply a pressure to the applied metal powder on the first adhesive layer for a time sufficient to densify the metal powder to at least about 90% and at most less than 100% dense in a pattern corresponding to the raised elements of the patterned die.

In other exemplary embodiments, the system includes a second powder applicator for applying a metal powder to a second adhesive layer on the substrate, and a second patterned die having raised elements in the form of a pattern and configured to apply a pressure to the applied metal powder on the second adhesive layer for a time sufficient to densify the metal powder to at least about 90% and at most less than 100% dense in a pattern corresponding to the raised elements of the patterned die. In other exemplary embodiments, the system includes an overlayer applicator for applying an overlayer covering at least a portion of the densified metal powder after removing uncompressed metal powder from a portion of the adhesive layer.

The invention makes it possible to produce a suitably conductive pattern such as, for example, a circuit element on a continuous flexible web that may be wound up into a roll. Conductive patterns on a roll of continuous flexible web are useful for making electronic constructions such as electronic article surveillance (EAS) labels or tags and radio frequency identification (RFID) labels or tags in fast roll-to-roll processes that yield continuous rolls of labels or tags. The inventive method may be performed at low cost since it requires a minimum number of process steps and materials, does not require extreme, specialized or slow process steps, and minimizes process waste and pollution. In addition, the invention may allow for use of lower cost raw materials and continuous manufacturing processes. In some embodiments, the invention may also facilitate formation of flexible circuits on temperature sensitive substrates such as polymeric films.

The details of one or more embodiments of the invention are set forth in the accompanying drawings and the description below. Other features, objects, and advantages of the invention will be apparent from the description and drawings, and from the claims.

### BRIEF DESCRIPTION OF THE DRAWINGS

FIG. 1 is a cross-sectional view of an exemplary rotary hydraulic roll press and patternable flexible web including an adhesive applied to a substrate as used in an embodiment of the invention.

FIG. 2 is a cross-sectional view of the exemplary rotary hydraulic roll press and flexible web of FIG. 1 as used in the metal powder densification step of an embodiment of the invention.

FIG. 3 is a cross-sectional view of the exemplary patterned flexible web bearing an adhered, densified metal powder following the metal powder densification step of FIG. 2.

FIG. 4 is a perspective view of an exemplary electrically conductive circuit element pattern formed by densified metal powders adhered to an adhesive on a flexible web.

FIG. 5 is a cross-sectional view of an exemplary electrically conductive circuit element pattern adhered to an adhesive on the flexible web of FIG. 4 additionally including circuit components and an overlayer.

FIG. 6 is a schematic side view of an exemplary rotary hydraulic roll press system useful in manufacturing flexible circuits including adhered compressed metal powders according to an embodiment of the invention.

FIG. 7 is a schematic side view of another exemplary rotary hydraulic roll press system useful in manufacturing double-sided flexible circuits containing adhered compressed metal powders according to another embodiment of the invention.

FIG. 8 is a block diagram illustrating an exemplary radio frequency identification (RFID) system for document and file management using an exemplary radio frequency identification tag formed from the exemplary electrically conductive circuit pattern and circuit elements adhered to an adhesive on the flexible web of FIG. 4.

Like numbered reference numerals in the various drawings indicate like elements.

### DETAILED DESCRIPTION

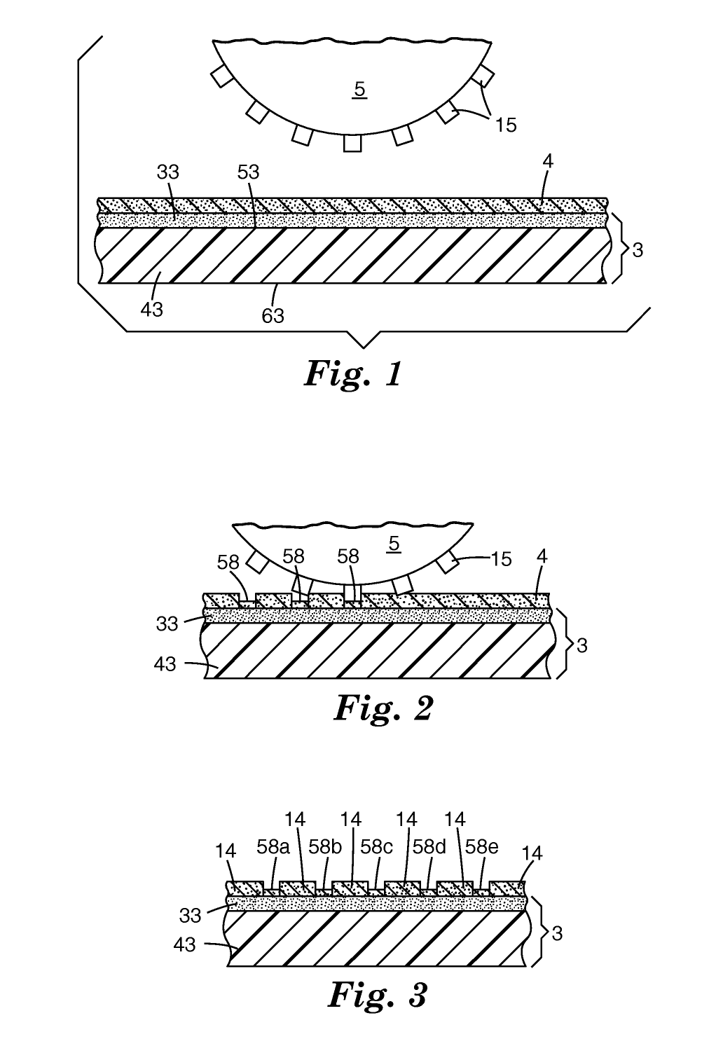

FIG. 1 is a cross-sectional view of an exemplary rotary hydraulic roll press and flexible web including an adhesive applied to a substrate as used in an embodiment of the invention. Referring to FIG. 1, a layer of a metal powder composition 4 is deposited onto a web 3 comprising two layers 33 and 43. The metal powder composition 4 comprises finely divided metal particles. Adhesive layer 33 comprises an adhesive, and substrate layer 43 comprises a flexible substrate. Adhesive layer 33 overlays substrate layer 43, and the metal powder composition 4 is not substantially adhered to the adhesive layer 33 until pressure is applied by die 5. That is, prior to the application of pressure by die 5, metal powder composition 4 is maintained in contact with adhesive layer 33 by, for example, maintaining web 3 in a horizontal position so that gravity holds the metal powder on top of adhesive layer 33.

Other possible methods to adhere the metal powder composition to the adhesive layer 33 may include use of electrostatic charges or magnetic fields, optionally in conjunction with ferromagnetic metal powder compositions. Although FIG. 1 and the following descriptive embodiments illustrate a metal powder composition 4 deposited onto a web 3 comprising an adhesive layer 33 applied to a substrate layer 43, it may be possible to apply the metal powder composition 4 to the adhesive layer 33 prior to or simultaneous with application of the adhesive layer 33 to the substrate 43.

It may also be possible to apply the metal powder composition 4 to the substrate 43 prior to or simultaneous with application of the adhesive layer 33 to the web. Suitable adhesives 33 to enable application of the metal powder composition 4 to the substrate 43 simultaneous with or prior to application of the adhesive to the substrate would include adhesives that are sufficiently mobile so as to migrate through the metal powder to produce an adhesive layer between the metal powder and substrate layer 43. In certain embodiments, the adhesive allows migration of metal powder to an extent that at least some metal powder is located on the surface of adhesive layer 33 opposite substrate 43 in a form that is suitable for subsequent compression, and the adhesive should be selected so that it provides adequate adhesion to substrate 43 and to the compressed metal powder after the compression step even if some metal powder remains dispersed in the adhesive layer 33.

The metal may be a malleable metal such as tin or copper. Aluminum may be used provided the surface of the metal powder is passivated to prevent formation of a surface oxide layer; however, use of 100% aluminum powder is generally not preferred due to the lower malleability of aluminum. Tin, for example, may be a preferred metal because of its malleability and because it is environmentally benign in landfills. However, other metals, including copper, aluminum, nickel, iron, steel, platinum, silver, gold, lead, zinc and the like may also be suitable for use in the metal powder composition in combination with tin. Copper may be a preferred metal for use in combination with tin, due to copper's excellent thermal and electrical conductivity. The metal powder composition 4 may contain only tin or it may contain two or more metals, in such combinations as a mixture of particles of two or more metals, of particles comprising alloys, blends or mixtures, of particles of one metal coated with a second metal, and the like. The metal powder composition may also include conductive non-metal powders, such as, for example, graphite.

The shape of the particles in the metal powder composition 4 may vary widely. The metal particles may be of the same shape or of different shapes and may be regularly or irregularly shaped. Exemplary particle shapes include, for example, spheres, oblongs, needles, dendrites, polyhedra (e.g., tetragons, cubes, pyramids and the like), prisms, flakes, rods, plates, fibers, chips, whiskers, and mixtures thereof. Similarly, the sizes of the metal particles in the metal powder composition 4 may vary widely, and may include monodisperse particles, a multi-modal distribution of particle sizes, or a broad distribution of particle sizes. In some embodiments, the particles in the metal powder composition 4 exhibit a mean particle size, expressed on a diameter basis, of approximately 0.01 micrometer to about 100 micrometers; preferably from about 0.1 micrometer to about 50 micrometers; most preferably from about 0.2 micrometer to about 10 micrometers.

One or more of the metal powders in the metal powder composition may optionally be treated to remove all or a portion of any surface oxides. Methods are known to those skilled in the art and vary for different metals, and include reduction (e.g., with hydrogen at elevated temperatures), washing with acidic or basic solutions, and the like. This treatment step may be carried out prior to application of the metal powder composition 4 to adhesive layer 33 (as shown in FIG. 1). Further, process steps including a metal powder composition that has been treated to remove surface oxides may be conducted in such a manner as to minimize the reformation of surface oxides prior to compression of the metal powder, for example, such as in an inert atmosphere.

The metal powder composition may include additional components and additives, for example, anti-caking agents, antistatic agents, dispersants, flow agents, colorants, cleaning agents, and anti-oxidants. In certain embodiments, for example, the final article contains metal particles including no more than about 5 percent by weight, preferably no more than about 3% by weight, and most preferably no more than about 1% by weight of additives.

Web 3 is a continuous sheet of flexible material including a substrate layer 43 having a first major surface 53 and a second major surface 63. Generally, the length of the web 3 in a processing direction is substantially greater than the width of the web 3 normal to the processing direction. In certain embodiments, the length of web 3 is at least 100 times larger than the width of web 3. Those skilled in the art understand that webs may be made continuous by splicing together web from one roll and web from another roll, thereby facilitating continuous processing of the web 3. Lengths of web 3 may be wound into rolls of flexible substrate bearing a pattern of densified metal after the process steps of the present invention.

The web 3 is flexible, which means that it may be bent by hand around a rod of approximately 2 cm in diameter, preferably 0.5 cm in diameter, without breaking, cracking or fracturing the web 3. Web 3 may be of any suitable thickness that maintains this flexibility. For example, web 3 may have a thickness of about 2000 microns or less, about 1000 microns or less; or preferably about 100 microns or less. The web 3 is preferably less conductive than the conductive metal pattern that is formed on the substrate surface through the practice of the present invention.

Preferably, the web 3 is provided in a roll form in which the web 3 is wound upon itself to form a cylindrical roll. In such cases, it is preferable that the adhesion between adhesive layer 33 and substrate 43 at first major surface 53 is greater than the adhesion between adhesive layer 33 and substrate 43 at second major surface 63, when adhesive layer 33 is in contact with second major surface 63 in a cylindrical roll. Optionally, a release liner may be positioned between the adhesive layer 33 and the second major substrate surface 63 opposite the adhesive layer 33, and the web 3 may be wound upon itself to form a roll. The release liner may act to inhibit adhesion of the adhesive layer 33 to the second major substrate surface 63 opposite the adhesive layer 33 (i.e. to the back side of substrate layer 43) when web 3 is wound into a roll.

Alternatively, a coating may be applied to second major substrate surface 63 opposite the adhesive layer 33 to prevent adhesion of the adhesive layer 33 to second major substrate surface 63 when web 3 is wound into a roll. In addition or alternatively, processes such as chemical or physical treatments may be applied to second major surface 63 to decrease adhesion of the adhesive layer 33 to second major surface 63. In some embodiments, processes such as chemical or physical treatments may be applied to first major surface 53 to increase adhesion of the adhesive layer 33 to first major surface 53. Manufacturers of polymers that are suitable as adhesives 33 may provide data sheets or other information concerning such treatments.

In certain embodiments, processing conditions during the application of adhesive layer 33 to first major surface 53 of substrate 43 may be selected to result in a post-application adhesion level of adhesive layer 33 to first major surface 53 of substrate 43 that is greater than the post-application adhesion level of adhesive layer 33 to second major surface 63 of substrate 43. In some embodiments, a different adhesion level of first major surface 53 and second major surface 63, respectively, may be a result of the process used to make substrate 43 which may, for example, have resulted in different surface structures or each major surface 53 and 63, such as different amounts of roughness, on major surfaces 53 and 63 of substrate 43. In one embodiment, both major surfaces 53 and 63 of substrate 43 contain layers of adhesive and any of the methods above, as well as selection of different adhesives for each face, may be used to produce a web 3 that can be wound into a roll, as well as cleanly unwound.

The web 3 may be a multi-layer construction. For example, as shown in FIG. 1, web 3 may be a two-layer construction. As noted above, a surface of substrate layer 43 may be overlaid by an adhesive layer 33. Preferably, the adhesive layer 33 is a continuous layer overlaying a major surface (e.g. a face) of the substrate layer 43, for example, first major substrate surface 53 or second major substrate surface 63.

One or more optional additional layers may also be included (not shown in FIG. 1). For example, a surface release layer, an antistatic layer, a protective layer and the like may be applied to the second major surface 63 opposite the adhesive layer on first major surface 53. One or more optional interlayers may optionally be interposed between the adhesive layer 33 and the substrate layer 43. For example, an interlayer may be an antistatic layer or a reinforcing layer. In another embodiment, an adhesive layer 33 may overlay first major surface 53 of substrate 43, and another adhesive layer 33′, that may be the same or different adhesive material than the adhesive material(s) in the first adhesive layer 33, may overlay second major surface 63 of substrate 43.

Suitable substrate layers 43 for the practice of this invention may be made from a variety of polymers, including thermoplastic, thermoset, and crosslinked polymers. Examples of suitable polymers include polyesters, polyimides, polyurethanes, polyolefins (e.g., polyethylene and polypropylene), polystyrene, cellulose acetate, and suitable combinations thereof. Substrate layer 43 may optionally receive additional chemical or physical treatment, such as calendering, embossing, surface treatment (e.g. plasma treatment, corona treatment, flame treatment, silanization, primer coating) and the like.

Substrate layer 43 may optionally include inorganic filler particles, such as ceramics, metal oxides (e.g., tantalum oxide) and high dielectric constant ceramics (e.g., barium titanate, barium strontium titanate, titanium dioxide, and lead zirconium titanate, and mixtures thereof). Other suitable ceramic fillers include silica, precipitated silica, zirconia, alumina, glass fibers, and the like. Suitable non-ceramic fillers include polymer fibers and carbon fibers. Other additives include, for example, dyes, pigments, plasticizers, sizing agents, anti-oxidants, flame retardants, and the like.

The web 3 includes an adhesive layer 33 overlaying the substrate layer 43. One adhesion level for adhesive 33 and major surfaces 53 of substrate layer 43 may be achieved by treatments or processes including, for example, those listed above, and a second adhesion level for adhesive layer 33 and major surface 63 of substrate 43 that is different than the adhesive level at surface 53 may be achieve by various methods including for example those listed above.

Adhesive 33 may preferably adhere to substrate roll 43 and in some embodiments does not substantially adhere to metal powder composition 4 in the absence of pressure from die 5, under useful process conditions such as those described in the Examples. The adhesion of adhesive 33 to compressed metal powder 58 (FIG. 2) should be at least as great as, and preferably is greater than, adhesion of compressed metal powder 58 to raised rotary die portions 15 during the compression step.

Adhesive materials suitable for use in adhesive layer 33 in the practice of this invention may include homopolymers and copolymers [collectively (co)polymers] such as (co)polymers of ethylene and ethyl acrylate, (co)polymers of ethylene and vinyl acetate, acid modified (co)polymers of ethylene and vinyl acetate, (co)polymers of ethylene and methacrylic acid, partially neutralized (co)polymers of ethylene and methacrylic acid, (co)polymers of ethylene and acrylic acid, partially neutralized (co)polymers of ethylene and acrylic acid, (co)polymers of ethylene and alkyl acrylic esters, (co)polymers of ethylene and alkyl acrylic esters modified with anhydride or acid groups, (co)polymers of ethylene and octene, syndiotactic polypropylene and the like. It will be understood that the ratios of monomers selected for use in a (co)polymer may vary. Manufacturers of suitable adhesive materials generally provide data sheets that teach combinations of substrate layers 43 suitable for use with particular adhesive layers 33.

Suitable adhesive materials for forming adhesive layer 33 may include (co)polymers manufactured for use as hot melt adhesives. Hot melt adhesives are generally characterized as solid-like materials exhibiting a melting temperature above which the adhesive softens, flows and behaves as a liquid-like material. According to certain embodiments of the invention, a hot melt adhesive composition is used as the adhesive layer 33 at a temperature below the melting temperature of the hot melt adhesive composition.

Adhesive layer 33 may be pre-formed on or pre-applied to substrate layer 43 in a process line that is different than the process line used to apply and density the metal powder composition. In some embodiments, adhesive layer 33 may be formed on or applied to substrate layer 43 in an in-line process immediately before applying metal powder composition 4 to adhesive layer 33. By immediately before, the metal powder composition 4 may be applied to adhesive layer 33 within ten minutes, more preferably within five minutes of the time at which adhesive layer 33 is applied to substrate layer 43. In other embodiments, adhesive layer 33 is pre-formed on or pre-applied to substrate layer 43 more than ten minutes before applying metal powder composition 4 to adhesive layer 33.

Adhesive layer 33 may be applied to substrate layer 43 by virtually any application method, such as in-situ polymerization, lamination, extrusion, roller coating, curtain coating, extrusion die coating, knife coating, spray coating, and the like. Adhesive layer 33 may be coated from water, an organic solvent, a mixture of organic solvents, or a mixture of water and organic solvents. Adhesive layer 33 may be applied as a solvent-less (e.g. 100% solids) composition. Adhesive layer 33 may include additives, for example, fillers, dyes, pigments, plasticizers, tackifiers, sizing agents, anti-oxidants, flame retardants, and the like. In some embodiments, the thickness of the adhesive layer 33 is selected to be between about 0.1 to about 5.0 mils (about 2.5 to 125 micrometers).

Any suitable method may be used to deposit the metal powder composition onto the substrate, such as, for example, notch bar coating, knife coating, hopper-fed knife coating, dipping, sifting, screening, spraying, blowing, or application of a fluidized bed of the metal powder composition. The metal powder composition may be applied in a single application or in multiple applications, with the same or different metal powder compositions, depending on the desired conductivity and thickness of the conductive pattern in the finished product.

Adhesive layer 33 should generally adhere well to substrate layer 43 and preferably does not substantially adhere to metal powder composition 4 in the absence of pressure from die 5. In addition, the adhesive 33 may be selected so that adhesion of the surface of projections 15 of die 5 to compressed metal powder 58 is preferably less than both the adhesion between the adhesive layer 33 and the substrate layer 43 and the adhesion between the compressed metal powder 58 and the adhesive layer 33, in order to avoid offset of either the compressed metal powder 58 or adhesive layer 33 to the surface of die 5 during the compression step.

Die 5 has projections or extending male portions 15. Although it is not visible in the cross-sectional representation in FIG. 1, the projections 15 of die 5 are shaped to produce a pattern of densified metal powder 58 on the surface of adhesive layer 33. Any pattern may be formed onto the surface of die 5 and thereby be imparted to metal powder composition 4 to form a pattern of densified metal 58 on web 3 during the compression step. Exemplary patterns include, for example, straight or curved lines, grids, coils, circles, rectangles, triangles, hexagons and other geometric shapes which may be either solidly filled or outlines of these shapes, irregular shapes, symbols, logos, text (letters and numbers) and combinations thereof.

Referring to FIG. 2, in one embodiment of the invention, die 5 is applied with pressure so that the projections 15 compress metal powder composition 4 to produce a compressed (e.g. densified) powder region 58 corresponding to a projection 15 on the surface of the die 5. The densified powder composition in region 58 adheres to the adhesive layer 33, while the non-compressed metal powder composition is not adhered to the adhesive layer 33. During this process step, the adhesion of the surface of projection 15 of die 5 to densified metal 58 is preferably less than the adhesion of the adhesive layer 33 to the densified metal 58 and preferably also less than the adhesion of the adhesive layer 33 to the substrate 43 at face 53, in order to avoid transfer of the densified metal 58 or the adhesive layer 33 to the projections 15 of the die 5. The surface of die 5 including projection 15 may be coated with refractory materials, for example titanium nitride, or the metal used to make the die, for example stainless steel, may be polished to a smooth surface.

The metal powder composition 4 is applied to the adhesive layer 33 overlaying substrate layer 43 on web 3, and compressed for a time and at a pressure sufficient to form an electrically conductive pattern of densified metal powder. The compressed, densified metal powder should exhibit a density greater than that of the uncompressed metal powder. In certain embodiments, the densified metal powder may be less than 100% dense, that is, the densified metal powder may exhibit a density less than that of a bulk metal including the same elements as the metal powder.

Compression of the metal powder may result in densification less than 100% due to the physical properties of the compressed powder, such as, for example, levels of impurities, crystal or grain size, grain interfaces or boundaries and the like. In certain preferred embodiments, the metal powder is compressed for a time and pressure sufficient to densify to at least about 50% dense, more preferably at least about 90% to at most less than 100% dense relative to the corresponding bulk metal or metal alloy.

The processing conditions used to produce the electrically conductive pattern will vary depending on the metal powders selected for use in the metal powder composition, as well as the properties of the substrate material. Application dwell times and pressures should preferably be selected to substantially minimize, and preferably eliminate damage to the web 3, such as melting, warping, wrinkling, buckling, blistering, decomposing, and the like.

Preferably, application dwell times are selected to be less than about 20 milliseconds, more preferably less than about 15 milliseconds, most preferably less than about 10 milliseconds, so that rapid processing speeds, often described as line speeds in the practice of roll-to-roll processing, may be achieved. In certain embodiments, lines speeds correspond to a linear web speed of at least about 5 cm per second, more preferably at least about 15 cm per second.

As for pressure, it may be difficult to measure the pressure applied to a compressible metal powder composition 4 formed as a layer on a substantially incompressible adhesive layer 33 formed on a substantially incompressible substrate layer 43, because it is generally not possible to accurately know the exact area being compressed at any particular time with a deformable contact interface in a process employing a rotary die. One possible pressure measurement technique, however, is to feed pressure paper, for example, SPL Pressurex™ High Pressure paper (available from Sensor Products LLC, East Hanover, N.J.) into the nip between a die and a back-up platen, in an effort to determine the applied pressure and pressure profile through the contact interface. The Topaq™ pressure impression analysis service provided by SPL may be used to extract the pressure distribution and pressure magnitude from variations in color and optical density of the impression formed on the pressure paper. Based on measurements with pressure paper, the desired applied pressure may range from about 450 atmospheres (about 6615 pounds per square inch) to about 1400 atmospheres (20,580 pounds per square inch), and suitable pressures are in the range from about 487-1351 atmospheres (7162-19862 pounds per square inch). Generally, higher pressures are preferred, provided that the applied pressure is not so high as to damage or distort the web 3.

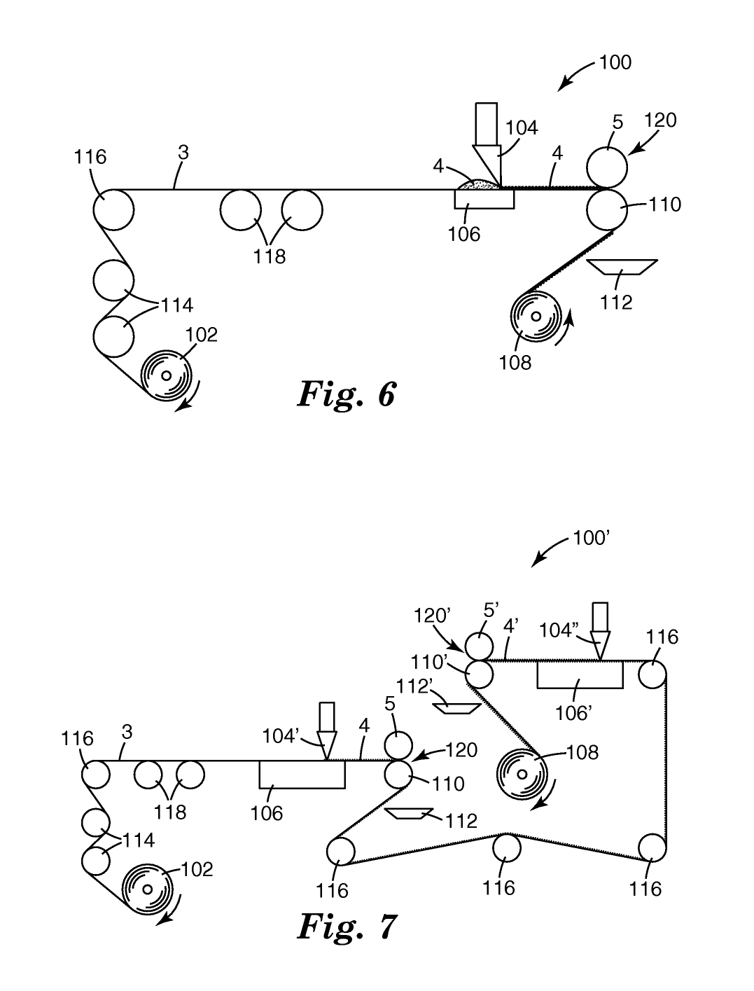

The metal powder densification step may be performed in a continuous process using, for example, a rotary die and rotary platen arrangement as illustrated by FIGS. 6-7, or in a batch-wise or step-and-repeat process, for example, using a flat die and platen in a hydraulic press. Webs may be handled in the form of cylindrical rolls having a range of widths and lengths. Webs may include sheets supported on webs, and the like. The use of the present invention in the practice of large-scale, continuous manufacturing will be apparent to those skilled in the art of roll-to-roll web handling processes.

Repetitive densification steps using the same or different metal powder compositions on the same or different areas of web 3 may be performed, for example, to give a thicker densified region consisting of multiple layers of the same metal powder composition, or to provide discrete layers of two or more densified metals, or to provide different metals in different areas of web 3, or to meet specific product requirements for the final article.

Referring to FIG. 3, once the die 5 is removed, a pattern of densified metal powder composition 58a-e adheres to the adhesive 33 in regions that were compressed by contact with the projections 15 on die 5, while the metal powder composition remains non-adhered to the adhesive layer 33 on the web 3 in regions 14 that were not compressed by contact with the projections 15 on die 5.

The residual, non-adhered metal powder composition in uncompressed regions 14 may optionally be substantially removed from the substrate by a variety of conventional methods, for example, compressed air, vacuum, vibration, brushing, blowing, gravity, aqueous wash, and suitable combinations thereof. As shown in FIG. 3, the densified metal powder composition in regions 58a-e that have been subjected to pressure by the projections 15 of die 5 adhere sufficiently to the adhesive layer 33 so that after removal of die 5, the non-adhered metal powder composition in regions 14 may subsequently be substantially removed without removing the densified, adhered metal powder composition in regions 58a-e. Metal powder composition that is removed may optionally be recycled, for example, by collection in a catch pan or vacuum device.

Optionally, the article comprising the metal pattern 58 on web 3, after removal of non-adhered powder in regions 14, may be subjected to one or more additional processing steps such as exposure to additional pressure or heat on selected portions of the article surface or on the entire article. In some embodiments, these additional processing steps may smooth the web 3 or further densify the metal powder composition 4. Web 3 may optionally receive additional chemical or physical treatment, such as calendering, embossing, surface treatment (e.g. plasma treatment, corona treatment, flame treatment, silanization, primer coating) and the like.

In other embodiments, the metal pattern 58a-e on web 3 may undergo a densification process to further increase the density (and hence the conductivity) of the metal powder in the metal pattern 58. Substrate material may be handled in the form of narrow or wide webs, sheets, sheets supported on webs, and the like, and the use of this invention in the practice of large-scale manufacturing will be apparent to those skilled in the art.

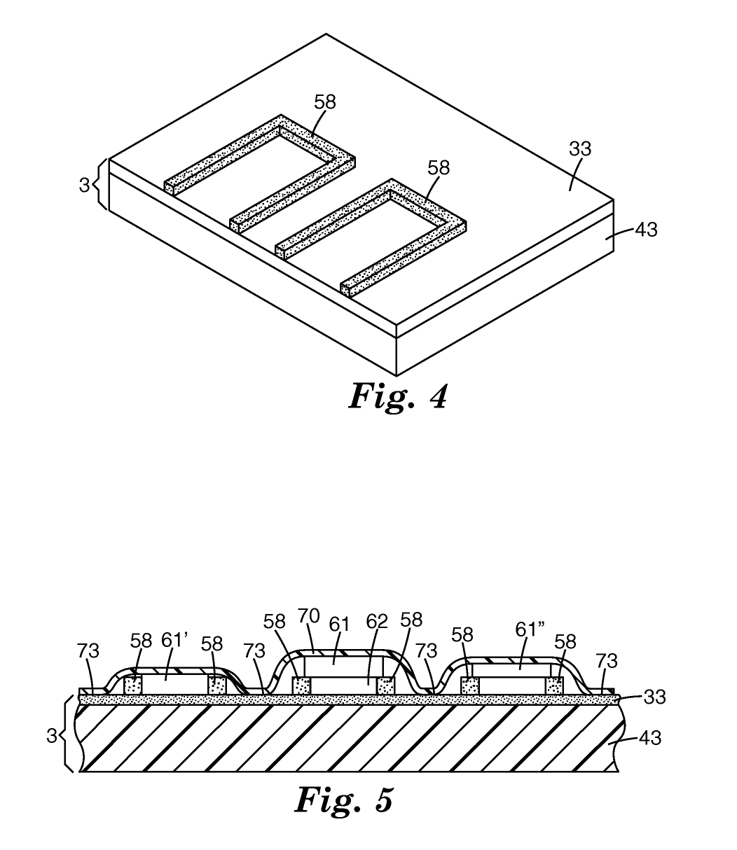

Referring to FIG. 4, the resulting article may include circuit elements formed by a densified, conductive metal pattern 58 adhered to a surface of adhesive layer 33 overlaying the substrate 43 of the web 3. A circuit element may be any metal pattern or shape or combination of metals, patterns and shapes that may comprise all or part of an element that is found in a functional electrical device. Exemplary circuit elements include circuit traces that provide electrically conductive paths or connections, resistors, fuses, capacitors or capacitor plates, inductive coils, antennas and the like.

The circuit element is preferably electrically conductive, and the resistivity of the compacted metal powder measured in the densified pattern region 58 is therefore preferably sufficiently low to pass an electrical current. However, because at least a portion of the compressed, densified metal powder may remain in particulate form, the resistivity may be greater than the resistivity of the fully dense metal in the bulk state. For example, the resistivity of fully dense tin is 11.1 microohm-cm. The resistivity of compressed, densified tin powder according to certain exemplary embodiments of the invention is about 19.0 microohm-cm, measured in an area that was subjected to a pressure of about 952 atmospheres (14,000 pounds per square inch). Generally, it is preferable to achieve as low a resistivity as possible without damaging or distorting web 3. Preferably, the resistivity is about 2 to about 50 microohm-cm.

Measurements of electrical conductivity in areas that are not compressed show an “open circuit” (i.e. no measurable conductivity) even when there is still a small amount of residual metal powder present, as is left after simply allowing metal powder to fall off the surface of the adhesive layer 33 with no additional cleaning. This demonstrates a densified, adhered conductive pattern 58 may be prepared without having to use a special step to clean off the last traces of tin dust from the uncompressed areas.

A Figure of Merit (FOM) may be used to compare the resistivity of a compressed (e.g. densified) metal powder to the minimum possible theoretical resistivity for the bulk metal in a fully dense state, according to the following equation:

% FOM=(R_{theoretical}/R_{measured})×100%,

where R_{theoretical} is the theoretical resistivity for the bulk metal in a fully dense state, and R_{measured} is the resistivity determined from the measured resistance of a sample of the compressed (e.g. densified) powder pattern. R_{measured} of a sample may be obtained by measuring the resistance for a particular sample, and normalizing for the cross-section and length of that particular sample to calculate R_{measured}. The method of the present invention may be used to make articles comprising circuit elements with a conductive pattern having a Figure of Merit greater than about 5%, preferably greater than about 10%, and more preferably greater than about 15%.

The conductive pattern 58 preferably adheres well to the adhesive layer 3, and withstands moderate bending and abrasion. For example, adhesion of the metal pattern to the adhesive layer 33 may be determined by measuring the resistance of the metal pattern to removal or damage during and after the bending of the article around rods of various diameters. The change in resistance upon bending depends on the components of the metal powder composition and the adhesive material. Preferably, articles including the circuit elements will withstand bending around a rod of diameter of about 25 mm, more preferably about 10 mm, without significant resistance increases.

The article including circuit elements may optionally undergo further additional processing steps such as conversion, lamination, patterning, etching, coating, assembly and the like. Additional layers or articles may be applied and these additional layers may also comprise electrically conductive patterns.

Referring to FIG. 5, a component 61, 61′ or 61″; for example an electronic component such as an integrated circuit, a light emitting diode, a holder or package for an integrated circuit, and the like; may be adhered to the adhesive layer 33, optionally using an additional optional adhesive layer 62 over a portion of adhesive layer 33. In some embodiments, the optional adhesive layer 62 is preferably selected to be an electrically conductive adhesive, such as an adhesive conductive film, optionally containing metal spheres, a conductive paste or a conductive ink, and the optional adhesive layer 62 may function not only to adhere the component 61 to the adhesive layer 33 on substrate layer 43 of web 3, but may also function to electrically connect the component 61 to the electrically conductive circuit element 58. In one embodiment, component 61 overlays at least a portion of electrically conductive circuit element 58. In another embodiment not shown in FIG. 5, component 61 overlays at least a portion of electrically conductive circuit element 58 and at least a portion of optional adhesive layer 62 is located between component 61 and circuit element 58 in the region where they overlay. In one embodiment, the component 61′ directly overlays adhesive layer 33, and component 61′ may be electrically connected to electrically conductive circuit element 58 by various methods, for example, wire bonding or application of a conductive paste or ink.

Alternatively, another component 61″, which may be an electronic component, may at least partially overlay the pattern 58 formed by the densified metal powder composition 4 and the adhesive layer 33. In some embodiments not illustrated in FIG. 5, the component 61″ may be sufficiently flexible to conform and adhere to the adhesive layer 33 when a force of sufficient magnitude is applied to the component 61″. In other embodiments not illustrated in FIG. 5, component 61″ may be applied under conditions, for example sufficient pressure and heat, such that adhesive 33 and optionally at least a portion of electrically conductive pattern 58 conform so that component 61″ is adhered to adhesive 33.

Optionally, component 61″ may be electrically connected to electrically conductive pattern 58 by various means, for example by direct contact, through conductive bumps on component 61″ and so on. One example of an electrically conductive pattern 58 construction formed by processes of this invention employing a component is an integrated circuit (IC) that is a radio frequency identification (RFID) IC wherein the IC is positioned to overlay a portion of an electrically conductive circuit element that forms an RFID antenna, wherein said RFID integrated circuit is electrically connected to said RFID antenna, thereby producing an RFID transponder.

In certain additional embodiments illustrated by FIG. 5, an overlayer 70 may cover at least a portion of the densified metal powder 58, and optionally, additional components, for example electronic components, that are adhered to the surface of the adhesive layer 33. The overlayer 70 may be a coating or film that adheres to the surface of the adhesive layer 33 at one or more adhesive contact points 73. The overlayer 70 may also be useful to provide adhesion to layers or articles that are added to the overlayer surface in subsequent steps. The overlayer 70 may also be a protective coating or a facestock suitable for receiving a printed layer, and the like. Overlayer 70 may be applied in a process that promotes adhesion of adhesive layer 33 to overlayer 70 at adhesive contact points 73, for example, by utilizing heat and pressure during the application of overlayer 70 so that adhesive 33 can at least partially melt. In this example, no additional adhesive would be required to adhere overlayer 70 to web 3.

The composition of the overlayer is not particularly limited, and may comprise, for example, a polymer or copolymer, an adhesive, a label material, or other conformable materials. In certain embodiments, the overlayer 70 comprises paper. In other exemplary embodiments, the overlayer 70 is used in combination with one or more electronic components 61, 61′ or 61″ electrically connected to an electrically conductive circuit element 58 that is an antenna to form an assembly that is a radio frequency identification tag.

The process steps of the invention may be conducted at ambient or slightly elevated temperatures. Lower process temperatures result in reduced processing costs and also enable the use of substrate materials that are not stable at high temperatures. It is advantageous to be able to select substrate materials for a variety of properties including flexibility, surface energy, environmental stability, reuse or recyclability, chemical composition, low cost and so on, as may be required to meet various product specifications, without being limited by process temperature requirements.

In further embodiments, the invention provides a system 100 for making a continuous flexible substrate bearing a pattern of compressed metal powder. Referring to FIG. 6, in one embodiment, the system 100 comprises a powder-coating and rotary die densification system. A web 3 comprising an adhesive layer overlaying a substrate may be fed from a rotating supply roll 102 and passed through a powder-coating station 106 comprising a knife edge 104 for controlling the thickness of metal powder composition 4 on adhesive layer 33.

For example, a quantity of metal power 4 is placed on adhesive layer 33 up-web from the knife edge 104, and metal powder moves with the web under the knife edge to produce a metal powder composition 4 of controlled thickness on adhesive layer 33 on web 3 down-web from the knife edge. The metal powder composition 4 is applied to the adhesive layer at the powder-coating station 106 to produce a web 3 bearing a coating of metal powder composition 4. The web 3 bearing a coating of metal powder composition 4 moves to a pattern-forming die station 120, illustrated in FIG. 6 by a rotary die 5 backed by a rotary platen 110. The web 3 bearing a pattern of densified metal 58 may be wound on a core positioned on take-up roll 108.

Although FIG. 6 depicts a generally cylindrical rotating roller configuration for rotary platen 110, other platen geometries are also within the scope of the invention, and in particular a non-rotating curved or even flat platen geometry may be employed. The rotary platen 110 may also function as a turning roller to deflect the coated web surface downward as shown in FIG. 6, thereby causing a substantial portion of the non-adhered metal powder to fall off under the influence of gravity into a collection pan 112. Alternatively, removal of the non-adhered metal powder could be carried out with additional stations (not shown in FIG. 6) that might use a contact brush, fluid (e.g. water, air, or inert gas) stream, air knife, adhesive contact roller, vibratory bar, or other methods or additional components or stations to remove uncompressed metal powder from the surface of the adhesive layer 33 after the web 3 passes rotary die 5.

FIG. 6 illustrates additional rollers that may be useful in a system 100 for practicing the method for making a continuous patterned flexible substrate. For example, tensioning rollers 114, turning rollers 116, and back-up rollers 118 may be used to facilitate movement of the web 3 through the powder-coating station 106 and the pattern-forming die station 120. Optionally, other additional rollers (not shown in FIG. 6) may be used to provide additional pressure or temperature or combinations thereof to the web 3 bearing a pattern of densified metal. For example, two rollers opposite one another could be used to apply pressure to the web 3 bearing a pattern of densified metal 58 after non-adhered metal powder is removed but before wind-up on take-up roll 108.

FIG. 6 illustrates a number of structures useful in a system 100 for making a continuous patterned flexible substrate, for example, a single powder-coating station 106, a single pattern-forming die station 120 comprising a rotary die 5, and rotary platen 110 (rotary platen 110 also functioning as a turning roller for removal of non-adhered powder). However, it is understood that the number and types of structures may be varied, and that the specifically disclosed structures may be replaced with other equivalent structures without departing from the scope of the present invention.

In particular embodiments, the system 100 may include additional powder-coating stations 106, each followed by an additional pattern-forming die station 120 (e.g. a die 5 and platen 110 arrangement), may be arranged in tandem on a single web-handling system to apply multiple metal powder layers or multiple patterns to the adhesive surface of the web 3. Alternatively, the web 3 may be repeatedly processed through a single pattern-forming die system having a single powder-coating station 106 and a single pattern-forming die station 120 (e.g. a die 5 and platen 110 arrangement), to produce multiple powder layers or multiple densified metal patterns 58 adhered on an adhesive on a substrate of web 3. In either system for applying multiple powder layers or multiple patterns, the metal powder composition 4 or thickness may be varied from one powder-coating station to another, and the pattern may vary from one pattern-forming die station 120 to another.

Optionally, additional coating stations or die stations may also be used in systems employing methods to invert the web after a first metal powder-coating and die impression. For example, a substrate coated with adhesive on both faces may be passed through a first metal powder-coating station and pattern-forming die station 120 to make a first conductive pattern on a first face of the substrate, and this may be followed by a station to invert the web, thereby removing non-adhered metal powder and presenting a second substrate face with adhesive. This could then be passed through a second metal powder-coating station 106 and pattern-forming die station 120 to make a conductive pattern on a second face of the substrate.

In further embodiments, the invention provides a system 100′ for making a patterned flexible substrate having a pattern of densified metal on each of two major surfaces of a web 3 (e.g. a double-sided flexible circuit). An exemplary system for producing a conductive metal pattern on two major surfaces of an adhesive-coated web 3 is shown in FIG. 7, which illustrates an in-line tandem process using two sequential metal powder coating stations 106 and 106′ including, for example, hopper fed knife applicators 104′ and 104″, each followed by a pattern-forming die station 120 or 120′, respectively, wherein sequential application of a patterned rotary die 5 or 5′ to the metal powder compositions 4 and 4′ coated on adhesive layers formed on major surfaces 53 and 63 of substrate 43, acts to compress, densify and adhere metal powder in patterns corresponding to the respective die patterns.

Referring to FIG. 7, a web 3 comprising adhesive layers overlaying each major surface 53 and 63 of a substrate 43 is fed from a rotating supply roll 102 and passed through a first powder-coating station 106 comprising a first hopper fed knife applicator 104′. A metal powder composition 4 is applied to a first adhesive layer 33 on first major surface 53 of substrate 43 at the first powder-coating station 106 to produce a first powder-coated side of web 3. The web 3 bearing a coating of metal powder composition 4 moves to a first pattern-forming die station 120 illustrated in FIG. 7 by a first rotary die 5 backed by a first rotary platen 110.

Although FIG. 7 depicts a generally cylindrical rotating roller configuration for first rotary platen 110, other platen geometries are also within the scope of the invention, and in particular a non-rotating curved or even flat platen geometry may be employed. The first rotary platen 110 may also function as a turning roller to deflect the coated web surface downward as shown in FIG. 7, thereby causing a substantial portion of the non-adhered metal powder to fall off into a collection pan 112. Alternatively, removal of the non-adhered metal powder could be carried out with additional components or stations (not shown in FIG. 7) that might use a contact brush, fluid (e.g. water, air, or inert gas) stream, air knife, adhesive contact roller, or other methods to remove uncompressed metal powder from the adhesive surface after the web 3 passes rotary die 5.

Web 3 bearing a pattern of densified metal 58 then passes through a set of web-inverting turning rollers 116, and then web 3 passes to a second powder-coating station 106′ including, for example, a second hopper fed knife applicator 104″. A metal powder composition 4′, which may, but need not be compositionally identical to metal powder composition 4, is applied to a second adhesive layer on second major surface 63 of substrate 43 at the second powder-coating station 106′ to produce a second powder-coated side of web 3 bearing a coating of metal powder composition 4′.

The second major surface 63 of substrate 43 bearing an adhesive layer and a coating of metal powder composition 4′, moves to a second pattern-forming die station 120′ illustrated in FIG. 7 by a second rotary die 5′ backed by a second rotary platen 110′. After passing through rotary die 5′, non-adhered metal powder 4′ is removed. The double-side coated web 3, bearing patterns of compressed and densified metal powder compositions 58 adhered to the adhesive layer 33 on the first major surface 53 of substrate 43 and the adhesive layer on the second major surface 63 of substrate 43, respectively, of web 3, may be wound on take-up roll 108.

Although FIG. 7 depicts a generally cylindrical rotating roller configuration for second rotary platen 110′, other platen geometries are also within the scope of the invention, and in particular a non-rotating curved or even flat platen geometry may be employed. The second rotary platen 110′ may also function as a turning roller to deflect the coated web surface downward as shown in FIG. 7, thereby causing a substantial portion of the non-adhered metal powder to fall off into a second collection pan 112′. Alternatively, removal of the non-adhered metal powder could be carried out with additional stations (not shown in FIG. 7) that might use a contact brush, fluid (e.g. water, air, or inert gas) stream, air knife, adhesive contact roller, vibratory bar, or other methods to remove uncompressed metal powder from the adhesive surface after the web 3 passes second pattern-forming die station 120′.

FIG. 7 illustrates additional rollers that may be useful in a system 100′ for practicing the method for making a continuous patterned flexible substrate. For example, tensioning rollers 114, turning rollers 116, and back-up rollers 118, may be used to facilitate movement of the web 3 through the powder-coating stations 106 and 106′ and the pattern-forming die stations 120 and 120′ including rotary dies 5 and 5′. Optionally, other additional rollers (not shown in FIG. 7) may be used to provide additional pressure or temperature or combinations thereof to the web 3. For example, two rollers opposite one another could be used to apply pressure to one or both web surfaces (sides) bearing a pattern of densified metal 58 after non-adhered metal powder is removed but before wind-up on take-up roll 108. Although FIG. 7 illustrates one particular embodiment for turning web 3 so that both faces of web 3 can face up for at least a portion of the metal powder composition and densification steps that at least partially rely upon gravity to keep the metal powder coatings in contact with the adhesive prior to compression, other methods for turning a web or for coating both sides of a web are known to those skilled in the art.

FIG. 7 also illustrates a number of structures useful in a system 100′ for making a continuous patterned flexible substrate, for example, first and second powder-coating stations 106 and 106′ including first and second hopper fed knife applicators 104′ and 104″; and first and second pattern forming die stations 120 and 120′ including rotary dies 5 and 5′ and rotary platens 110 and 110′ (also functioning as turning rollers for removal of non-adhered powder). However, it is understood that the number and types of structures may be varied, and that the specifically disclosed structures may be replaced with other equivalent structures without departing from the scope of the present invention.

As noted above, in certain embodiments, the invention relates to a method for forming a flexible electrical circuit element. A circuit element is any metal pattern or shape or combination of metal patterns and shapes that may comprise all or part of an element that is found in a functional electrical device. Examples include traces that provide electrically conductive paths or connections, connection pads, capacitors or capacitor plates, resonant coils, resistors, fuses, inductive coils, bridges, antennas and the like.

In exemplary embodiments, the techniques may be used to provide an article that may include all or part of one or more electrical components for use in an electromagnetic communication circuit. The circuit may be used in a communication system. An example article is a radio frequency identification (RFID) tag. Exemplary electrical components include an antenna, connector pads for bridges or jumpers, connector pads for integrated circuits, circuitry, capacitor plates, capacitors, bridges, fuses and the like. In one embodiment, the invention provides at least a major portion of the antenna, such that web 3, bearing the adhered, densified metal powder composition in the form of a pattern 58, also forms a major layer in the construction of the RFID tag. Optionally, the RFID tag is a combination tag that includes an RFID element and a magnetic security element.

In another exemplary embodiment, the techniques may be used to provide an article that may include one or more of the components for use in an Electronic Article Surveillance (EAS) system. Resonant labels or tags useful in EAS systems may be used, for example, to provide protection from theft in retail stores, and in some applications it may be preferable for the label to contain exemplary components that may include a fuse, capacitor, resonant coil, or other components whose properties and performance in combination with other components may be changed by the application of a current, voltage or electromagnetic field.

In yet another embodiment, the techniques may be used to provide an article with at least one connection pad electrically connected to at least one integrated circuit (including but not limited to integrated circuits made on a silicon wafer substrate, often referred to as die or chips). For example, a conductive metal pattern on web 3 may form connection pads and also be connected (directly or via conductive adhesive, solder, wire-bonding or the like) to an integrated circuit, to provide an article in which electrical connection of an external device or article to the integrated circuit is accomplished by contacting and making an electrical connection to the connection pad of the conductive metal pattern.

The integrated circuit may be bare or packaged. In this example, the connection pads of the conductive metal may be formed larger than the connection sites on the integrated circuit, to allow for easier access and connection by the external device or article, particularly if the dimensions of the integrated circuit and the attach pads on the integrated circuit are small (less than approximately 2 mm). The foregoing description may describe an electronic package or, in the case of certain integrated circuits, a package that may be referred to as a strap.

In yet another embodiment, the techniques may provide electrical components that are resistors and fuses. The process may employ different materials or conditions to produce these components. For example, the use of combinations of different metal powders, (such as copper, tin, or an alloy such as steel) may yield traces of lower conductivity (higher resistivity) suitable as resistors and fuses.

Variations in materials or process conditions, for example, densification pressure, may also result in traces suitable as resistors and fuses. Additionally, traces of the same metal powder may be pressed at varying widths to achieve varying resistance for use as resistors or fuses. Furthermore, it may be useful to combine components of higher and lower conductivity, for example by electrically connecting traces of higher and lower conductivity (wider and narrower widths, respectively) to create a resistor or fuse in parallel or series with a conductive component. Such combinations of components could also be made with different combinations of metal powder, arranged to give sections of higher and lower conductivity.

Those skilled in the art will recognize that under different conditions of use, components of this invention may behave differently. For example, under one applied voltage or applied current, a component may function as a conductive trace, while under a second applied voltage or applied current, a component may function as a fuse.

In a further embodiment, the techniques provide electrical connection to a battery or to make a battery electrode. The techniques of the invention may further be used to make articles wherein the conductive metal pattern provides at least one connection to or provides components of sensors, such as chemical sensors, medical sensors and physical sensors. The invention may also be used to make connections to components of displays. Combinations of these are also within the scope of the invention. For example, a battery life sensor may comprise conductive metal patterns that connect a battery to an indicating display.

In yet another embodiment, the invention also provides electrical components of systems. Examples of such systems are wireless tracking or surveillance systems. For example, in a radio frequency identification (RFID) system, the invention may provide an antenna coupled to a radio frequency identification reader and at least a portion of a RFID tag applied to individual articles, for example, books or files. In another example, the techniques may be used to provide one or more electrical components used in a resonant label, applied to or contained within the packaging of retail goods and used as part of a system to provide protection from theft in retail stores (also known as Electronic Article Surveillance or EAS systems).

In another embodiment, the invention provides components of hardgoods or hardware. For example, the invention may provide an antenna that is incorporated into an RFID reader or an RFID shelf, as described in U.S. Pat. No. 6,816,125, the entire disclosure of which is incorporated herein by reference.

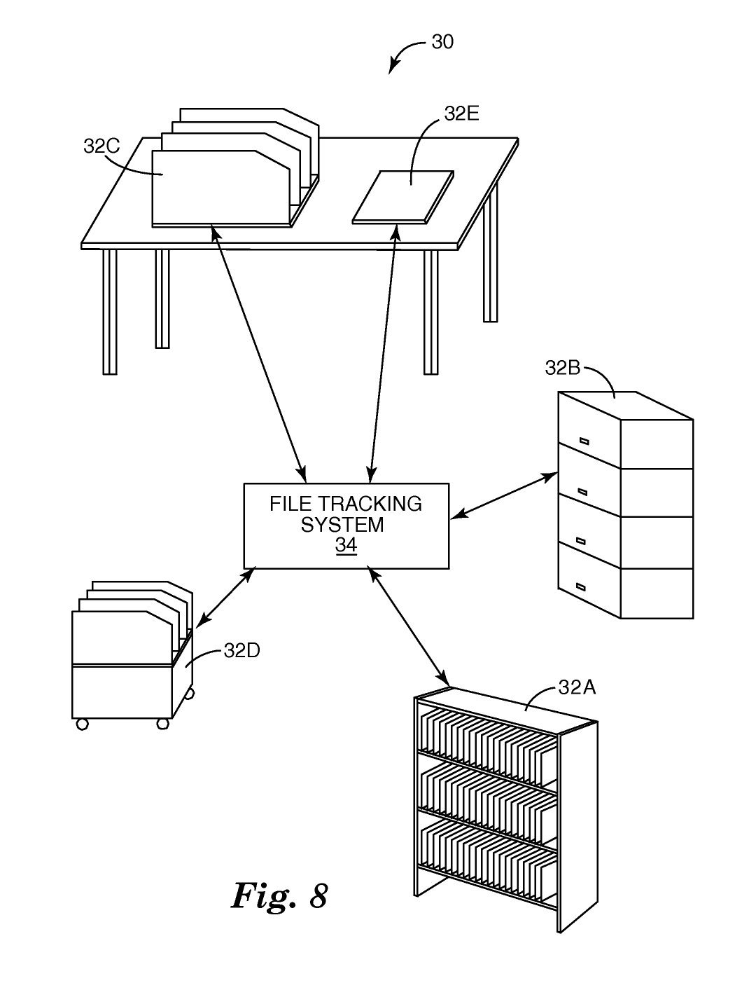

FIG. 8 is a block diagram illustrating an exemplary radio frequency identification (RFID) system 30 for document and file management. As described, the techniques for manufacturing articles by compressing a metal particle composition may be used to produce one or more electrical components for use in one or more electromagnetic communication circuits of RFID system 30. Law offices, government agencies, and facilities for storing business, criminal, and medical records rely heavily on files of paper documents. These files may be positioned in a number of “smart storage areas” 32, e.g., on an open shelf 32A, a cabinet 32B, a vertical file separator 32C, a smart cart 32D, a desktop reader 32E, or a similar location, as shown in FIG. 8. RFID tags may also be used in other systems, for example, as labels applied to shipping containers such as corrugated cardboard shipping cartons. In such applications, RFID tags may be used to track location of a package or carton in transport from one location to another.

RFID tags may be associated with or applied to items of interest. The tag may be embedded within the item or the packaging of the item so that the tag is at least substantially imperceptible, which may help to prevent detection and tampering. Items may be “source-marked” with a RFID tag, such as applying or incorporating a RFID tag to an item during its manufacture, as with a file folder, document, book, or the like. Each of the smart storage areas 32 of system 30 may be equipped with one or more antennas for interrogating the files to aid in determining which files are located at each of the storage areas.

For example, one or more antennas are positioned within open shelve 32A to create an electromagnetic field for communicating with the RFID tags associated with the files. Similarly, antennae may be located within cabinet 32B, vertical file separator 32C, smart cart 32D, desktop reader 32E, and the like. The antennas may be positioned in various ways, such as on top or bottom of each shelf, at the back of the shelves, or supported vertically, interspersed among the files. The antennas may be retrofitted to existing shelves or built into a shelf and purchased as a unit. For example, an antenna on a flexible substrate may be incorporated into a shelf during the manufacturing of the shelf, by treating the flexible substrate with a saturant and then laminating the substrate to other materials used in the construction of the shelf.

In other applications, RFID systems employ RFID tags or labels that are applied to other objects, for example, pallets, shipping containers such as corrugated boxes and individual consumer items or the packaging materials of individual consumer items, and RFID readers that may be handheld readers, readers installed in equipment such as conveyor belts, printers, forklifts or trucks, or readers installed in buildings such as at doorways or portals. In another embodiment, the techniques may be used to provide components, for example antennas, for use in RFID tags and readers in such applications.

The techniques may be used to provide electrical components of an article having two or more planes within the article. Such articles are often referred to as multi-layer articles or multi-layer constructions. The invention provides various methods for their production. For example, a conductive pattern may be formed on one surface or on two or more surfaces of a flexible substrate material. Conductive patterns on two surfaces of a substrate may be the same or different and may be aligned or registered so that there is any desired amount of overlap (overlap as used herein refers to a section of the substrate which contains conductive material on both major surfaces).

In certain embodiments, an article with conductive metal patterns on two surfaces may be produced by making conductive patterns according to this invention on both sides of a web 3, provided that adhesive layers are provided on both sides of substrate layer 43. An exemplary system for producing a conductive metal pattern on two major surfaces of web 3 is shown in FIG. 7, which illustrates an in-line tandem process using two sequential metal powder applicators 106 and 106′, each followed by application of a rotary die 5 and 5′ to the powder coated surfaces of the web 3.

Any of the articles comprising a conductive pattern according to this invention may further comprise other parts, from prior, simultaneous or subsequent processing, including but not limited to conductive inks, conductive adhesives, metal foils, magnetic storage media, magnetic security media, solder, wire, saturants including oils, waxes, organic or inorganic polymerizable compositions and polymers, films, laminating adhesives, mechanical fasteners, integrated circuits, and discrete electrical components such as resistors, capacitors, diodes and the like. A web 3 having an electrically conductive pattern 58 may provide roll goods with advantages related to authentication, identification, tracking, detection, stealth, shielding, costs, and manufacturing processes.

In manufacturing, it may be desirable to minimize the number of steps used to manufacture an article in order to minimize the cost of the article. It may also be desirable to minimize the number of raw materials used, or to reuse or recycle raw materials in the manufacturing process. In some embodiments, a single metal powder may be used advantageously to reduce manufacturing cost.

The invention is further illustrated by the following examples, but the particular materials and amounts thereof recited in these examples, as well as other conditions and details should not be construed to limit this invention.

Example 1 illustrates one embodiment of a method for making flexible circuits using densified, adhered metal powders. In Example 1, a rotary die powder-coating and densification system was set up as shown in FIG. 6. An adhesive-coated substrate, Scotchpak™ film (Product # ES 29813, available from 3M Company, St. Paul, Minn.) was fed from a supply roll 102 and passed as a web 3 through a knife edge 104 of powder-coating station 106 to form a web 3 bearing a coating of metal powder composition 4 before moving to pattern forming die station 120 including a rotary die 5 backed by a rotary platen 110.

Tin powder (Aldrich Product Number 265632, Aldrich Chemical Co., Milwaukee, Wis.) was passed through a 400-mesh sieve and placed on the web 3 shortly before the knife-edge 104 (that is, the knife edge 104 was located down-web from the position where the metal powder was placed onto the web). Dams on either side of the web were used to confine the metal powder to the web, so that metal powder could be coated up to about the lateral edges of the web. A gap of 0.003 inches was maintained between the web and the knife edge to control the thickness of the applied metal powder composition layer. The web 3 was moved at a linear line speed of about 15 cm/sec (about 30 feet per minute).

The rotary die 5 and rotary platen 110 was used to compress areas of the web 3 bearing a coating of metal powder composition 4 conforming to raised pattern elements on the surface of rotary die 5, thereby densifying and adhering the metal powder to the web 3 in the compressed areas. The rotary die 5 comprised a cylindrical steel roller with raised elements forming patterns in the shape of antennas. The surface of rotary die 5 die was coated with titanium nitride. The cylindrical rotary platen 110 comprised a smooth, cylindrical steel roller. The cylindrical rotary platen 110 was set to a surface temperature of about 54° C. (about 130° F.). The tin powder coated web was passed between the rotary die 5 and the cylindrical rotary platen 110 to compress and thereby densify and adhere the tin powder to the adhesive layer on the web 3 in the areas contacted by the raised elements of the antenna pattern on the surface of rotary die 5.

The web 3 bearing a coating of metal powder composition 4; now compressed, densified and adhered in patterned areas; and uncompressed, non-adhered metal powder, was passed downward over the rotary platen 110, thereby causing a substantial portion of the non-adhered metal powder to fall from the adhesive surface into collection pan 112. The web 3, bearing the compressed, densified and adhered metal powder in the form of a pattern of antennas corresponding to the raised pattern elements on the surface of rotary die 5, was wound on take-up roll 108 to complete the process. The resistivity of the compressed, densified tin powder pattern was determined to be about 20.4 microohm-cm measured in an area that was subjected to a pressure of about 952 atmospheres (14,000 pounds per square inch).

Example 2 illustrates another embodiment of a method for making flexible circuits using densified, adhered metal powders. In Example 2, SCM L-10 tin powder (SCM Metal Products, Inc, Research Triangle Park, North Carolina) that had been passed through a 400-mesh sieve was applied to various adhesives overlaying a polyester substrate to form a web 3 using the apparatus shown in FIG. 6. The adhesives are listed in Table I.

TABLE I

| | | | Melt Flow | | |
|---|---|---|---|---|---|
| | | Percent | Index | | Vicat |
| | | Active | (@190° C., | Melting | Softening |
| | | Group | 2.16 kg | Point | Point |
| Product | Chemistry | (Wt. %) | for 10 Min) | (° C.) | (° C.) |
| Nucrel | Ethylene Methacrylic | 6.5 | 9.0 | 104 | 88 |
| 0609HS | Acid | | | | |
| (DuPont)¹ | | | | | |
| Bynel 1123 | Acid modified EVA | — | 6.7 | 74 | 50 |
| (DuPont) | | | | | |
| Bynel 2174 | Anhydride modified | — | 2.8 | 85 | 60 |
| (DuPont) | ethylene acrylate | | | | |
| Bynel 3859 | Anhydride modified | — | 4.3 | 75 | 62 |
| (DuPont) | Ethylene Vinyl Acetate | | | | |
| Elvaloy 2615 | Copolymer of Ethylene | 15 | 6.0 | 97 | 58 |
| AC (DuPont) | and Ethyl Acrylate | | | | |
| Elvax 360 | Ethylene and Vinyl | 25 | 2.0 | 78 | 53 |
| (DuPont) | acetate | | | | |
| Elvax 760Q | Ethylene and Vinyl | 9.3 | 2.0 | 100 | 82 |
| (DuPont) | acetate copolymer | | | | |
| Surlyn 1652-1 | Ethylene methacrylic | — | 4.5 | 100 | 79 |
| (DuPont) | acid copolymer - partial | | | | |
| | Zinc neutralized | | | | |
| Primacor 3150 | Ethylene acrylic acid | 3.0 | 11.0 | 104 | 89 |
| (Dow)² | copolymer | | | | |
| Primacor 3330 | Ethylene acrylic acid | 6.5 | 5.5 | 100 | 85 |
| (Dow) | copolymer | | | | |
| Primacor 3440 | Ethylene acrylic acid | 9.7 | 10.5 | 98 | 81 |
| (Dow) | copolymer | | | | |
| Primacor | Ethylene acrylic acid | 20.5 | 300 | 77 | 42 |
| 5980I (Dow) | copolymer | | (@125° C.) | | |
| Primacor 3340 | Ethylene acrylic acid | 6.5 | 9.0 | 101 | 84 |
| (Dow) | copolymer | | | | |

¹E. I. Dupont de Nemours Corp., Wilmington, DE.
²Dow Chemical Corp., Midland, MI

The line speed was the same as for Example 1. In this experiment, the platen roller surface temperature was set to about 71° C. (about 160° F.). The rotary die was rotated at a speed 100.8% of the web speed through the nip defined by the hopper-fed knife metal powder application station. The resistivity of the compressed, densified tin powder pattern was determined to be about 19.0 microohm-cm measured in an area that was subjected to a pressure of about 952 atmospheres (14,000 pounds per square inch). A sample of the flexible web 3 bearing the pattern 58 of densified tin powder composition was bent around a rod having a diameter of 0.62 mm, and the densified tin powder composition remained adhered to adhesive layer 33. The measured resistance of the electrically conductive pattern remained unchanged before and after bending at a value of 0.2 ohm measured over a length of about 35 mm.

Various embodiments of the invention have been described. These and other embodiments are within the scope of the following claims.

1. A process comprising:
applying an adhesive layer to a first surface of a flexible substrate;
applying a metal powder to the adhesive layer; and
compressing the metal powder on the adhesive layer for a time and at a pressure sufficient to form a pattern of densified adhered metal powder.

2. The process of claim 1, wherein compressing comprises applying a pressure to the metal powder to densify the metal powder to less than 100% dense.

3. The process of claim 1, wherein compressing comprises compressing the metal powder with a patterned die to form the pattern corresponding to raised elements of the patterned die.

4. The process according to claim 1, further comprising removing uncompressed metal powder from the adhesive layer.

5. The process according to claim 1, wherein the compressed metal powder exhibits a resistivity from about 2 to about 50 microohm-cm.

6. The process according to claim 1, further comprising:
applying a second adhesive layer to a second surface of a flexible substrate;
applying a metal powder to the second adhesive layer;
compressing the metal powder on the second adhesive layer on the second surface with a patterned die having raised elements in the form of a pattern, for a time and at a pressure sufficient to densify the metal powder to at least about 90% and at most less than 100% dense in a pattern corresponding to the raised elements of the patterned die; and
removing uncompressed metal powder from the second adhesive layer.

7. The process according to claim 1, further comprising applying an overlayer covering at least a portion of the densified metal powder.
